(19) United States
(12) Patent Application Publication
(10) Pub. No.: US 2023/0062572 A1
(43) Pub. Date: Mar. 2, 2023

(54) METHOD OF MANUFACTURING SEMICONDUCTOR DEVICE

(71) Applicant: TAIWAN SEMICONDUCTOR MANUFACTURING COMPANY, LTD., Hsinchu (TW)

(72) Inventors: Chung-Wei CHANG, Hsinchu (TW); Chin-Ming LIN, Hsinchu (TW); Peng SHEN, Hsinchu (TW); Bo-Wei CHOU, Hsinchu City (TW); Ping-Jung HUANG, Yunlin County (TW)

(73) Assignee: TAIWAN SEMICONDUCTOR MANUFACTURING COMPANY, LTD., Hsinchu (TW)

(21) Appl. No.: 17/460,742

(22) Filed: Aug. 30, 2021

(51) Int. Cl. H01L 21/02; H01L 21/311; H01L 29/417; H01L 29/78; H01L 29/66; B08B 3/08

(52) U.S. Cl. CPC H01L 21/02057; H01L 21/31111; H01L 21/31144; H01L 29/41791; H01L 29/7851; H01L 29/66545; H01L 29/6681; B08B 3/08; B08B 2203/007

(57) ABSTRACT

A method of forming a semiconductor device includes soaking a batch of wafers in a first cleaning liquid, replacing the first cleaning liquid with a second cleaning liquid, soaking the batch of wafers in the second cleaning liquid, and soaking the batch of wafers in an etchant. The first cleaning liquid has a first temperature. The second cleaning liquid has a second temperature. The etchant has a third temperature. The second temperature is between the first temperature and the third temperature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a method of forming a semiconductor device in accordance with some embodiments.

FIGS. 2-6 and 15-26 illustrate a semiconductor device at various stages of the method in FIG. 1 according to some embodiments of the present disclosure.

FIG. 7 is an exemplary block S105 for fabrication of a semiconductor device in accordance with some embodiments.

FIGS. 8-14 illustrate an exemplary apparatus 400 at various steps for fabrication of the semiconductor device in accordance with some embodiments of the present disclosure.

FIG. 27 is a chart illustrating time to temperature of soaking the batch of wafers in the etchant, according to some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are directed to, but not otherwise limited to, a fin-like field-effect transistor (FinFET) device. The FinFET device, for example, may be a complementary metal-oxide-semiconductor (CMOS) device including a P-type metal-oxide-semiconductor (PMOS) FinFET device and an N-type metal-oxide-semiconductor (NMOS) FinFET device. The following disclosure will continue with one or more FinFET examples to illustrate various embodiments of the present disclosure. It is understood, however, that the application should not be limited to a particular type of device, except as specifically claimed.

The fins may be patterned by any suitable method. For example, the fins may be patterned using one or more photolithography processes, including double-patterning or multi-patterning processes. The double-patterning or the multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

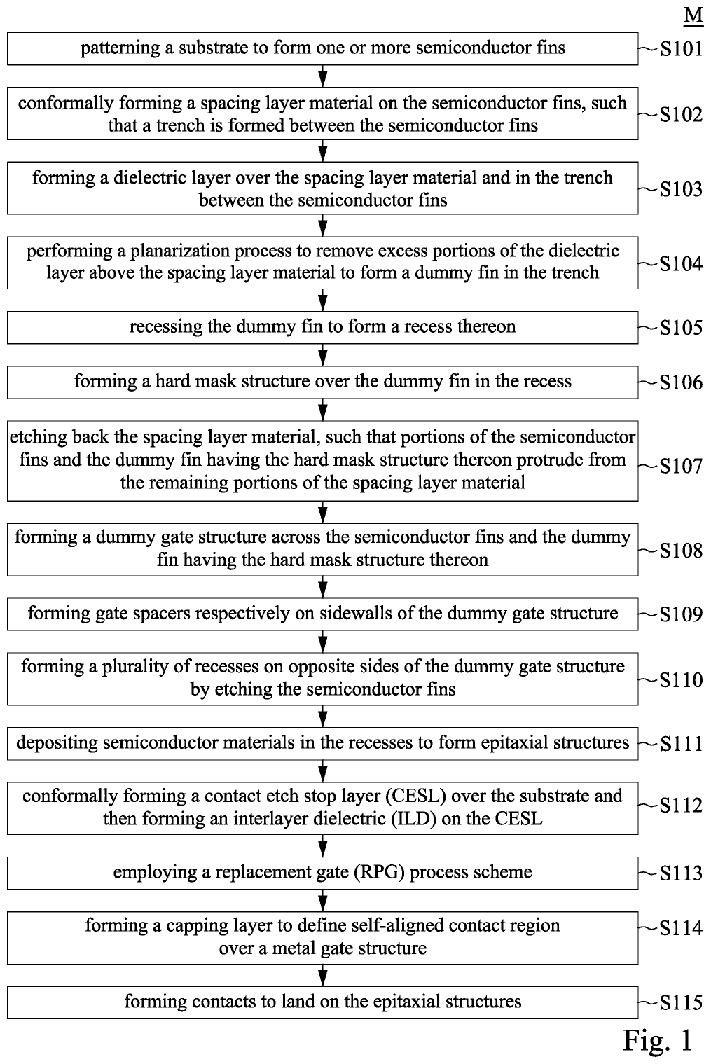

Referring now to FIG. 1, illustrated is an exemplary method M for fabrication of a semiconductor device in accordance with some embodiments. The method M includes a relevant part of the entire manufacturing process. It is understood that additional operations may be provided before, during, and after the operations shown by FIG. 1, and some of the operations described below can be replaced or eliminated for additional embodiments of the method. The order of the operations/processes may be interchangeable. The method M includes fabrication of a FinFET device. However, the fabrication of FinFET device is merely example for describing the manufacturing process according to some embodiments of the present disclosure.

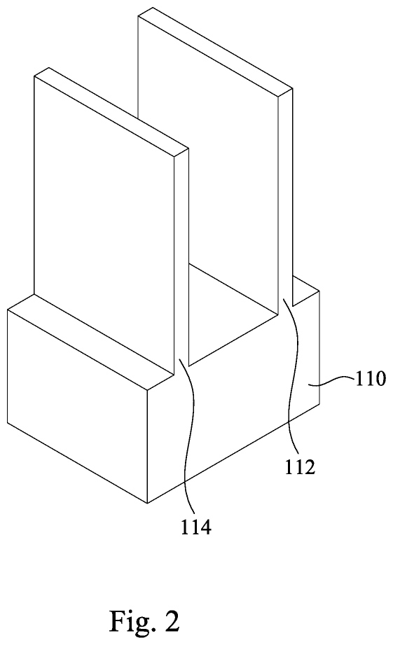

FIGS. 2-6 and 15-26 illustrate a semiconductor device 100 at various stages of the method M according to some embodiments of the present disclosure. The method M begins at block S101. Referring to FIG. 2, in some embodiments of block S101, a substrate 110 is provided. The substrate 110 includes at least one N-type region and at least one P-type region. At least one N-type device will be formed on the N-type region, and at least one P-type device will be formed on the P-type region. For ease of explanation, it is assumed that in FIGS. 2-6 and 15-26, the substrate 110 includes one N-type region and one P-type region adjacent the N-type region. In some embodiments, the substrate 110 may include silicon (Si). Alternatively, the substrate 110 may include germanium (Ge), silicon germanium (SiGe), gallium arsenide (GaAs) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method. In various embodiments, the substrate 110 may include any of a variety of substrate structures and materials.

A plurality of semiconductor fins 112 and 114 are respectively formed over the N-type region and the P-type region of the substrate 110. The semiconductor fins 112 and 114 may serve as active regions (e.g., channels and source/drain features) of transistors. It is noted that the numbers of the semiconductor fins 112 and 114 in FIG. 1 are illustrative. In addition, one or more dummy fins may be disposed adjacent both sides of the semiconductor fins 112 and/or 114 to improve pattern fidelity in patterning processes.

The semiconductor fins 112 and 114 may be formed, for example, by patterning and etching the substrate 110 using photolithography techniques. In some embodiments, a layer of photoresist material (not shown) is deposited over the substrate 110. The layer of photoresist material is irradiated (exposed) in accordance with a desired pattern (the semiconductor fins 112 and 114 in this case) and developed to remove a portion of the photoresist material. The remaining photoresist material protects the underlying material from subsequent processing operations, such as etching. It should be noted that other masks, such as an oxide or silicon nitride mask, may also be used in the etching process. The semiconductor fins 112 and 114 may be made of the same material as the substrate 110 and may continuously extend or protrude from the substrate 110. The semiconductor fins 112 and 114 may be intrinsic, or appropriately doped with an n-type impurity or a p-type impurity.

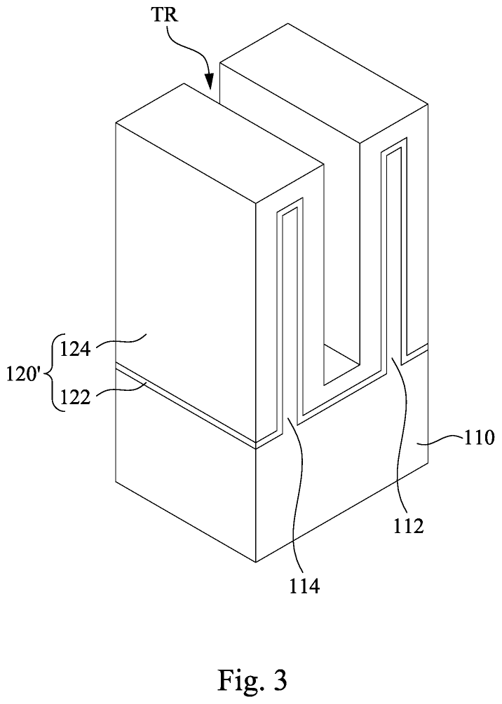

Returning to FIG. 1, the method M then proceeds to block S102 where a spacing layer material is conformally formed on the semiconductor fins, such that a trench is formed between the semiconductor fins. With reference to FIG. 3, in some embodiments of block S102, a spacing layer material 120′ is deposited on the semiconductor fins 112 and 114, such that a trench TR is formed between the semiconductor fins 112 and 114. In some embodiments, the spacing layer material 120′ can be made of dielectric materials. In some embodiments, the spacing layer material 120′ may be made of a dielectric material such as, for example, spin-on-glass, silicon nitride, silicon oxynitride, fluorine-doped silicate glass (FSG), a low-k dielectric material, and/or other suitable insulating material. In some embodiments, the spacing layer material 120′ is deposited by an ALD process. In some embodiments, the deposition of the spacing layer material 120′ can be done by suitable processes such as, for example, plasma-enhanced ALD (PEALD), CVD, PVD, molecular beam epitaxy (MBE), high density plasma CVD (HDPCVD), metal organic (MOCVD), remote plasma CVD (RPCVD), PECVD, other suitable methods, and/or combinations thereof.

In some embodiments, the spacing layer material 120′ includes a first liner layer 122 and a second liner layer 124. The first liner layer 122 is in contact with the substrate 110 and may be a dielectric layer, such as silicon oxide, silicon nitride, silicon oxynitride, SiCN, SiCₓO_{y}N_{z}, or combinations thereof. The second liner layer 124 is on and in contact with the first liner layer 122 and may be a dielectric layer, such as silicon oxide, silicon nitride, silicon oxynitride, SiCN, SiCₓO_{y}N_{z}, or combinations thereof. The first liner layer 122 and the second liner layer 124 have different materials. For example, the first liner layer 122 is a nitride layer, and the second liner layer 124 is an oxide layer. In some embodiments, the first liner layer 122 is omitted. In some embodiments, the second liner layer 124 is thicker than the first liner layer 122.

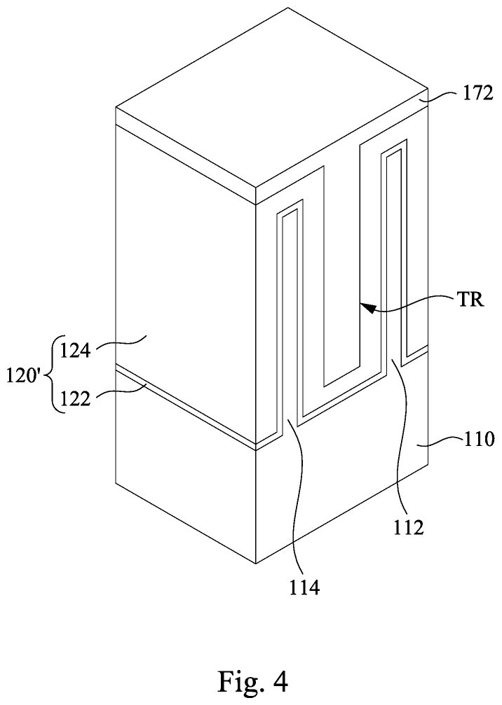

Returning to FIG. 1, the method M then proceeds to block S103 where a dielectric layer is formed over the spacing layer material and in the trench between the semiconductor fins. With reference to FIG. 4, in some embodiments of block S103, a dielectric layer 172 is conformally formed above the structure in FIG. 3. In greater detail, the dielectric layer 172 is formed over the spacing layer material 120′ and in the trench TR between the semiconductor fins 112 and 114. As shown in FIG. 4, the dielectric layer 172 substantially fills the trench TR between the semiconductor fins 112 and 114. In some embodiments, the dielectric layer 172 may include silicon nitride, silicon oxide, silicon oxynitride, SiCN, SiCON, SiOC, or other suitable materials. In some embodiments, the dielectric layer 172 is deposited with an ALD process or other suitable processes.

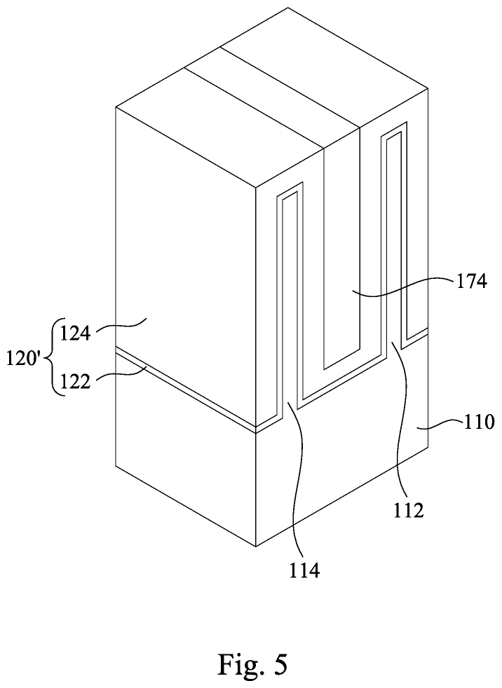

Returning to FIG. 1, the method M then proceeds to block S104 where a planarization process is performed to remove excess portions of the dielectric layer above the spacing layer material to form a dummy fin in the trench. With reference to FIG. 5, in some embodiments of block S104, a planarization (e.g., CMP) process is performed to remove excess portions of the dielectric layer 172 above the spacing layer material 120′ to form a dummy fin 174 in the trench TR.

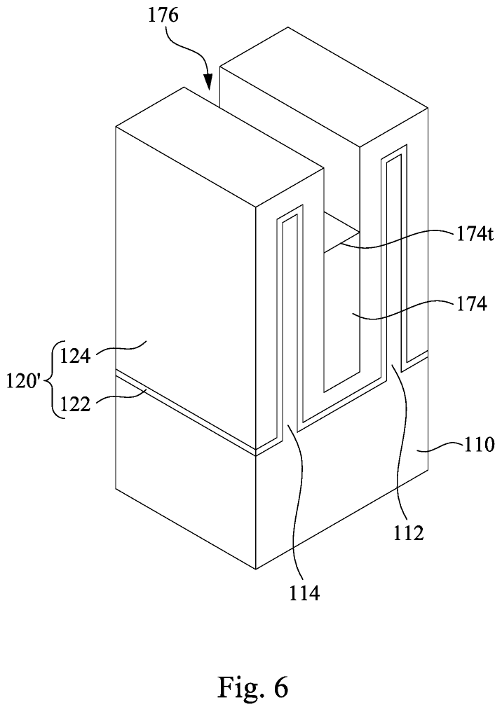

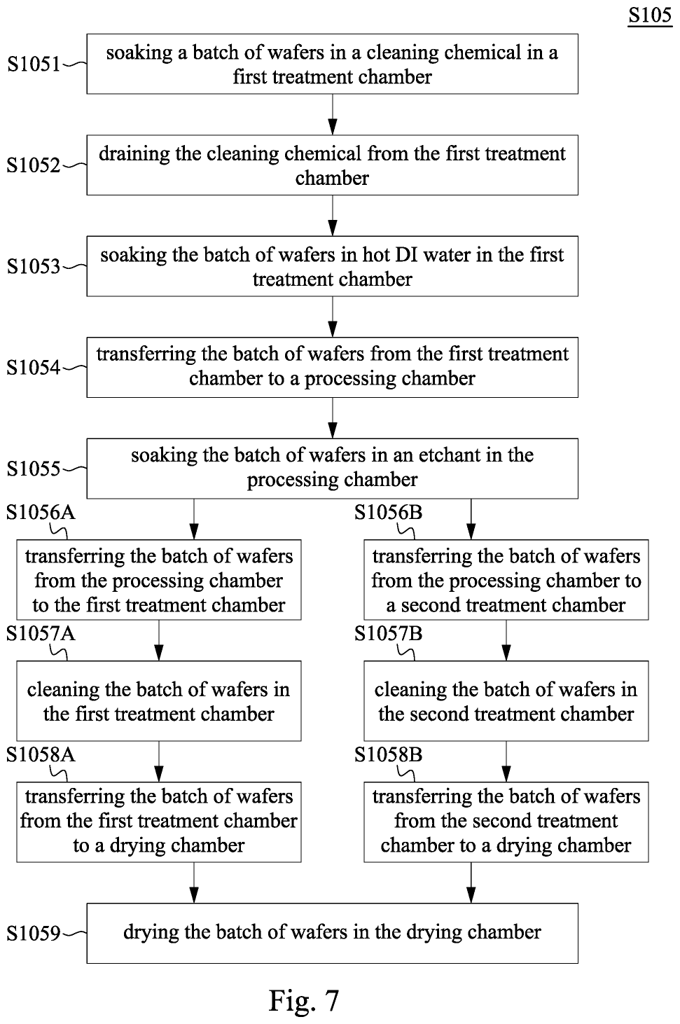

Returning to FIG. 1, the method M then proceeds to block S105 where the dummy fin is recessed to form a recess thereon. With reference to FIG. 6, in some embodiments of block S105, the dummy fin 174 is recessed to form a recess 176 thereon. In some embodiments, multiple processing processes are performed to recess the dummy fin 174. Details of the block S105 of recessing the dummy fin 174 are discussed in FIGS. 7-14.

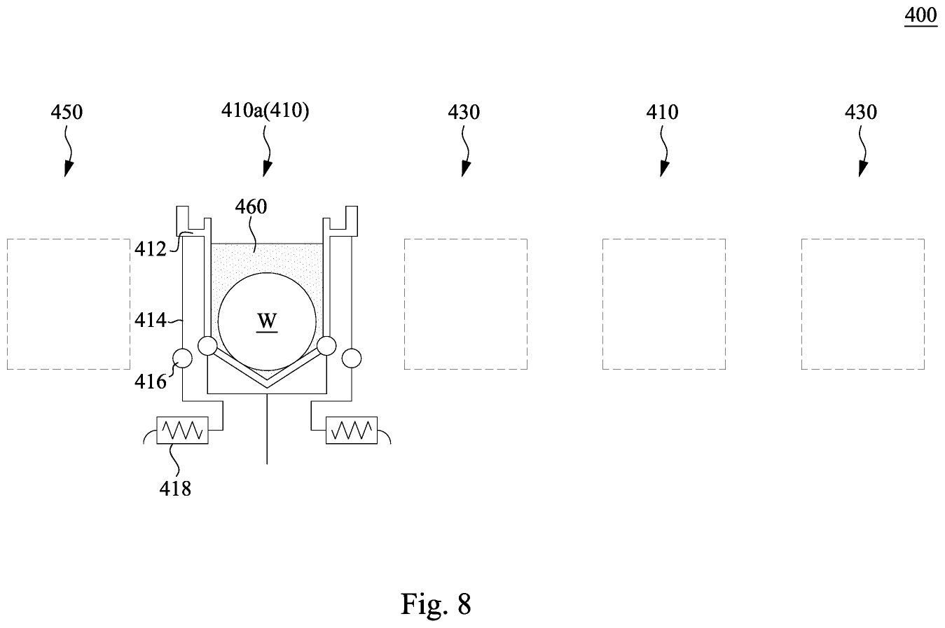

Reference is now made to FIGS. 7-14. FIG. 7 is an exemplary block S105 for fabrication of a semiconductor device in accordance with some embodiments, in which block S105 includes a plurality of steps that are utilized for recessing the dummy fin 174 in FIG. 6. FIGS. 8-14 illustrate an exemplary apparatus 400 at various steps for fabrication of the semiconductor device in accordance with some embodiments of the present disclosure.

The block S105 begins from step S1051 where a batch of wafers is soaked in a cleaning chemical in a first treatment chamber. With reference to FIG. 8, in some embodiments of step S1051, the apparatus 400 includes a plurality of treatment chambers 410, a plurality of processing chambers 430, and at least one drying chamber 450, and batch of wafers W is soaked in a cleaning chemical 460 in a first treatment chamber 410a of the apparatus 400. It is understood that details of the processing chambers 430 and the drying chamber 450 are not shown in FIG. 8. In some embodiments, the first treatment chamber 410a (and each of other treatment chambers 410) has a first liquid channel 412 leading to a cavity of the first treatment chamber 410a, a first liquid pipe 414 connected to the first liquid channel 412, a first pump 416 coupled to the first liquid pipe 414, and a first heater 418 coupled to the first liquid pipe 414.

The first liquid pipe 414 is further connected to a first liquid source, such that the cleaning chemical 460 provided by the first liquid source is sent to the first liquid channel 412 by the first pump 416. In some embodiments, the cleaning chemical 460 is heated before it enters the cavity of the first treatment chamber 410a, for example, the cleaning chemical 460 can be heated by the first heater 418 while passing through the first liquid pipe 414. In some embodiments, the cleaning chemical 460 is heated, and the temperature of the heated cleaning chemical 460 is in a range from about 25° C. to about 60° C. If the temperature of the cleaning chemical 460 is greater than about 60° C., unwanted oxide film etching loss might be the process concern; if the temperature of the cleaning chemical 460 is lower than about 25° C., the cleaning efficiency not enough for impurity removal. In some embodiments, the batch of wafers W is soaked in the first treatment chamber 410a for about 120 seconds to about 600 seconds. If the time of the batch of wafers W soaked in the cleaning chemical 460 is greater than about 600 seconds, the wafer process time would be too long and would not be economical for manufacturing industry; if the time of the batch of wafers W soaked in the cleaning chemical 460 is shorter than about 120 seconds, the liquid replacement (e.g. draining and filling) time is not enough and thus water mark defect might be occurred. In some embodiments, the cleaning chemical 460 is a standard clean-1 (SC1), where the SC1 is a mixture of deionized water (DI water), ammonium hydroxide (NH₄OH), and hydrogen peroxide (H₂O₂) at a mixture ratio of 5:1:1 of DINH₄OH:H₂O₂. This wet treatment may omit any chemical, such as hydrofluoric (HF) acid, that might remove contaminants from the surface of the batch of wafers W.

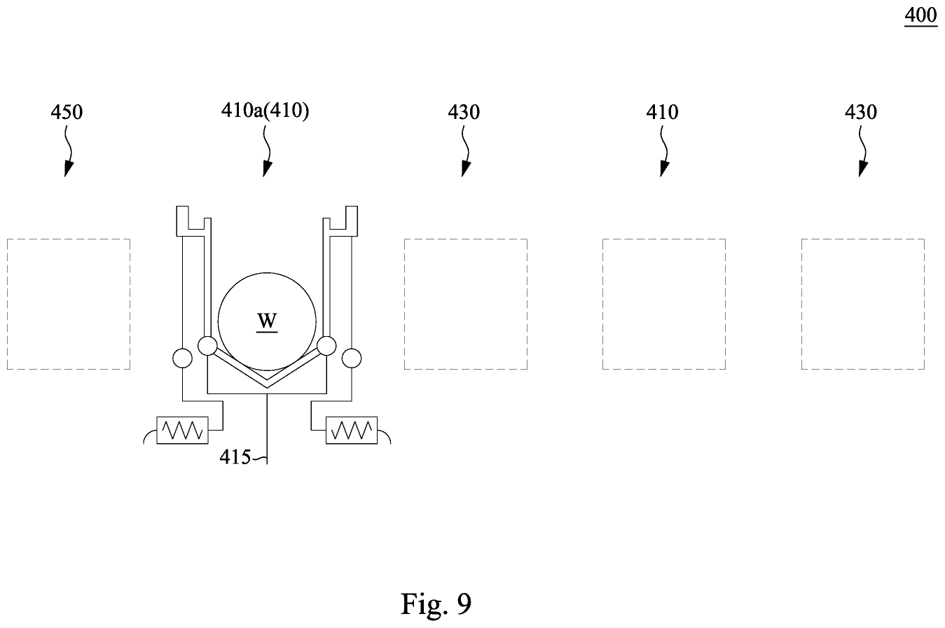

Returning to FIG. 7, the block S105 then proceeds to step S1052 where the cleaning chemical is drained from the first treatment chamber. With reference to FIG. 9, in some embodiments of step S1052, the cleaning chemical 460 with the removed contaminants is directly drained from the first treatment chamber 410a, for example, from a liquid outlet 415 at a bottom of the first treatment chamber 410a. During the step of draining the cleaning chemical 460, the batch of wafers W still stays in the first treatment chamber 410a. It is understood that details of the processing chambers 430 and the drying chamber 450 are not shown in FIG. 9.

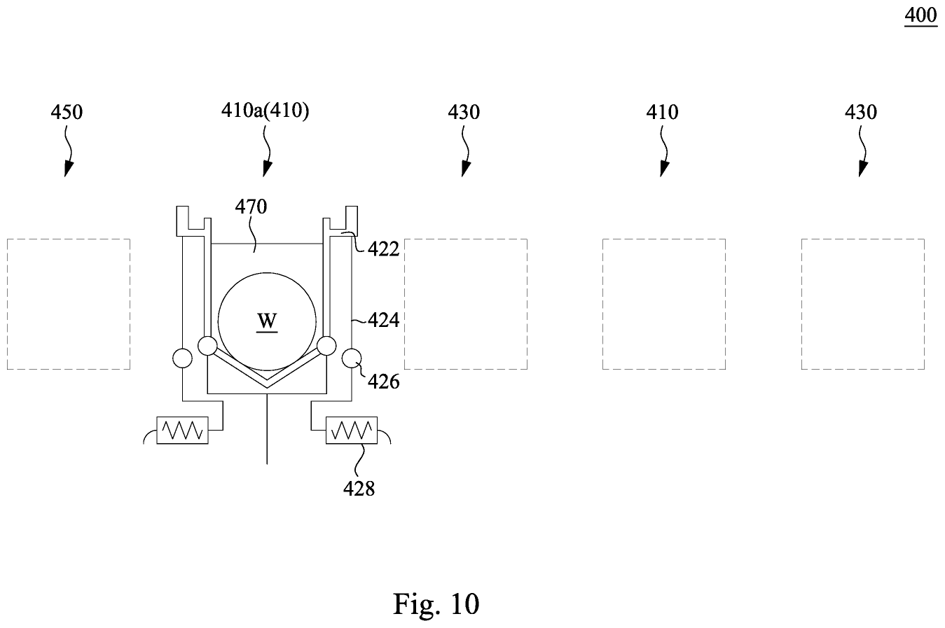

Returning to FIG. 7, the block S105 then proceeds to step S1053 where the batch of wafers is soaked in hot DI water in the first treatment chamber. With reference to FIG. 10, in some embodiments of step S1053, the batch of wafers W is soaked in the hot DI water 470 in the first treatment chamber 410a, such that the temperature of the batch of wafers W is raised and is in a range from about 60° C. to about 90° C.

In some embodiments, the first treatment chamber 410a (and each of other treatment chambers 410) further has a second liquid channel 422 leading to a cavity of the first treatment chamber 420a, a second liquid pipe 424 connected to the second liquid channel 422, a second pump 426 coupled to the second liquid pipe 424, and a second heater 428 coupled to the second liquid pipe 424. It is understood that details of the processing chambers 430 and the drying chamber 450 are not shown in FIG. 10.

The second liquid pipe 424 is further connected to a second liquid source, such that the DI water provided by the second liquid source is sent to the second liquid channel 422 by the second pump 426. In some embodiments, the DI water 470 is heated before it enters the cavity of the first treatment chamber 420a, for example, the DI water 470 can be heated by the second heater 428 while passing through the second liquid pipe 424. In some embodiments, the second is heated to a temperature higher than that of the cleaning chemical 460 (see FIG. 8). For example, the temperature of the hot DI water 470 is in a range from about 60° C. to about 90° C. If the temperature of the hot DI water 470 is greater than about 90° C., the boiling water would easily induce wafer collide with etch other thereby inducing wafer broken; if the temperature of the hot DI water 470 is lower than about 60° C., the clean efficiency would not be enough to clean the impurity. In some embodiments, the batch of wafers W is soaked in the hot DI water 470 in the first treatment chamber 410a for about 60 seconds to about 120 seconds, such that the temperature of the batch of wafers W and the temperature of the hot DI water 470 are balanced. If the time of the batch of wafers W soaked in the hot DI water 470 is greater than about 120 seconds, the wafer would be over heated; if the time of the batch of wafers W soaked in the hot DI water 470 is shorter than about 60 seconds, the wafer would not be evenly heated and would fall on impurity containment.

From step S1051 to step S1053, as described from FIG. 8 to FIG. 10, the batch of wafers W is contained in the first treatment chamber 410a and remains the same position in the first treatment chamber 410a. For example, the batch of wafers W is vertically disposed in the first treatment chamber 410a. Because the step S1051 to step S1053 are performed in same treatment chamber, the step S1051 to step S1053 can be also referred as to in-situ treatment.

Returning to FIG. 7, the block S105 then proceeds to step S1054 where the batch of wafers are transferred from the first treatment chamber to a processing chamber. In some embodiments, the hot DI water is drained from the liquid outlet of the first treatment chamber after the batch of wafers W leaves the first treatment chamber.

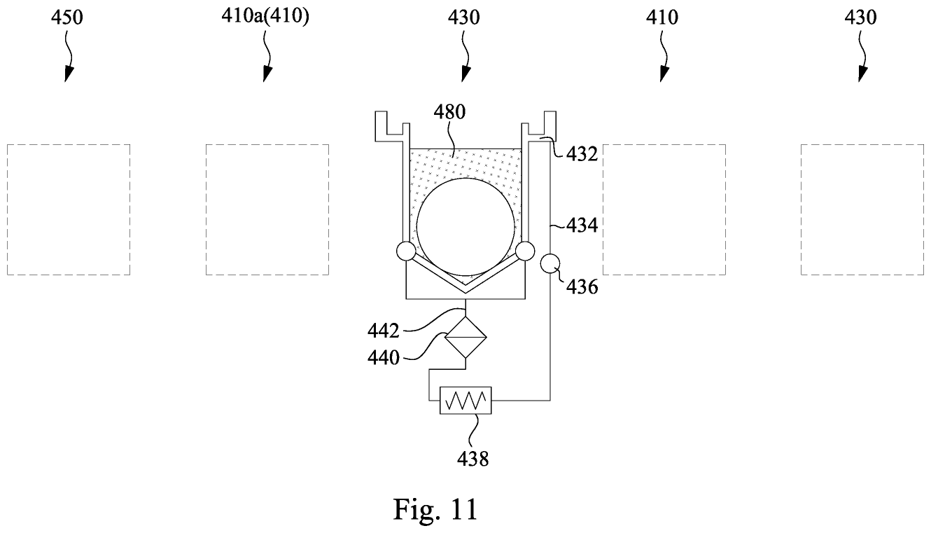

Returning to FIG. 7, the block S105 then proceeds to step S1055 where the batch of wafers is soaked in an etchant in the processing chamber. With reference to FIG. 11, in some embodiments of step S1055, the batch of wafers W is soaked in the etchant 480 in the processing chamber 430, such that a portion of the dummy fin 174 (see FIG. 6) is removed by the etchant 480 thereby recessing the dummy fin 174.

In some embodiments, the processing chamber 430 has a liquid channel 432 leading to a cavity of the processing chamber 430, a liquid pipe 434 connected to the liquid channel 432, a pump 436 coupled to the liquid pipe 434, a heater 438 coupled to the liquid pipe 434, and a filter 440 coupled to the liquid pipe 434. The liquid pipe 434 is further connected to a liquid outlet 442 of the processing chamber 430. It is understood that details of the treatment chambers 410 and the drying chamber 450 are not shown in FIG. 11.

In some embodiments, the dummy fin 174 includes nitride such as silicon nitride, and the second liner layer 124 of the spacing layer material 120′ (see FIG. 6) includes oxide such as silicon oxide. The corresponding etchant 480 thereof is selected to have high etching selectivity between nitride and oxide. In some embodiments, the etchant 480 is selected to have a higher etching rate to nitride (e.g. the dummy fin 174) than that to oxide (e.g. the second liner layer 124 of the spacing layer material 120′). In some embodiments, the etchant 480 a mixture of phosphoric acid (H₃PO₄) and water (H₂O).

The etchant 480 is sent to the liquid channel 432 by the pump 436. In some embodiments, the etchant 480 is heated before it enters the cavity of the processing chamber 430, for example, the etchant 480 can be heated by the heater 438 while passing through the liquid pipe 434. In some embodiments, the etchant 480 is heated to a temperature higher than that of the hot DI water 470 (see FIG. 10). For example, the temperature of the heated etchant 480 in the processing chamber 430 is in a range from about 140° C. to about 180° C., such as about 120° C. or about 180° C. If the temperature of the heated etchant 480 is greater than about 180° C., H₃PO₄ azeotropic point control avoid remains and occurs etching stop defect; if the temperature of the heated etchant 480 is lower than about 140° C., silica precipitate easily induce ball type defect. The batch of wafers W is soaked in the etchant 480 for about 50 seconds to about 600 seconds. If the time of the batch of wafers W soaked in the etchant 480 is greater than about 600 seconds, temperature of the chemical stable soaking time would be too high; if the time of the batch of wafers W soaked in the etchant 480 is shorter than about 50 seconds, the tank temperature would be easily influenced by batch size witch is the strong factor to etching rate.

The amount of the dummy fin 174 removed by the etchant 480 is controlled by the soaking time in the processing chamber 430.

The liquid pipe 434 has a first end connected to the liquid channel 432 and a second end connected to the liquid outlet 442 of the processing chamber 430. That is, the etchant 480 is recycled in the processing chamber 430. For example, after several batches of wafers W are processed in the processing chamber 430, the etchant 480 is collected and filtered by the filter 440. The etchant 480 passes the filter 440 and is heated by the heater 438 then enters the cavity of the processing chamber 430 by the pump 436 via the liquid channel 432.

As discussed above, the temperature of the batch of wafers W is sequentially raised from the step S1051, step S1053, and step S1055. In some embodiments, the temperature difference between step S1051 and step S1055 may be greater than 100° C., by pre-heating the batch of wafers W in step S1053 before the batch of wafers W is soaked in the etchant 480, such that the step S1053 may serve as a buffer stage between the low temperature step S1051 and the high temperature step S1055. That is, during the pre-cleaning stage (e.g. steps S1051 and S1053) of the batch of wafers W, the batch of wafers W is heated twice, and the temperature of the batch of wafers W is raised to approach the temperature of the wet-etching stage (e.g. step S1055).

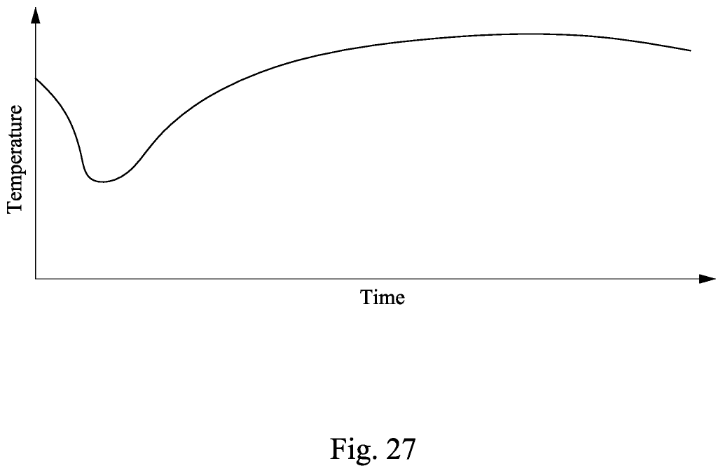

Reference is further made to FIG. 27, which illustrate time to temperature of the batch of wafers soaked in the etchant, such as the step S1055, according to some embodiments of the disclosure. The temperature variation (e.g. temperature drop) is well controlled and is reduced. In some embodiments, the pre-heating minimizes temperature drop value for at least about 50%. Furthermore, the temperature stable time and the variation of the temperature are also reduced accordingly. In some embodiments, the temperature stable time is efficiently shortened by about at least 33%.

Returning to FIG. 7, the block S105 then proceeds to step S1056A where the batch of wafers are transferred from the processing chamber to the first treatment chamber, in some embodiments of the disclosure.

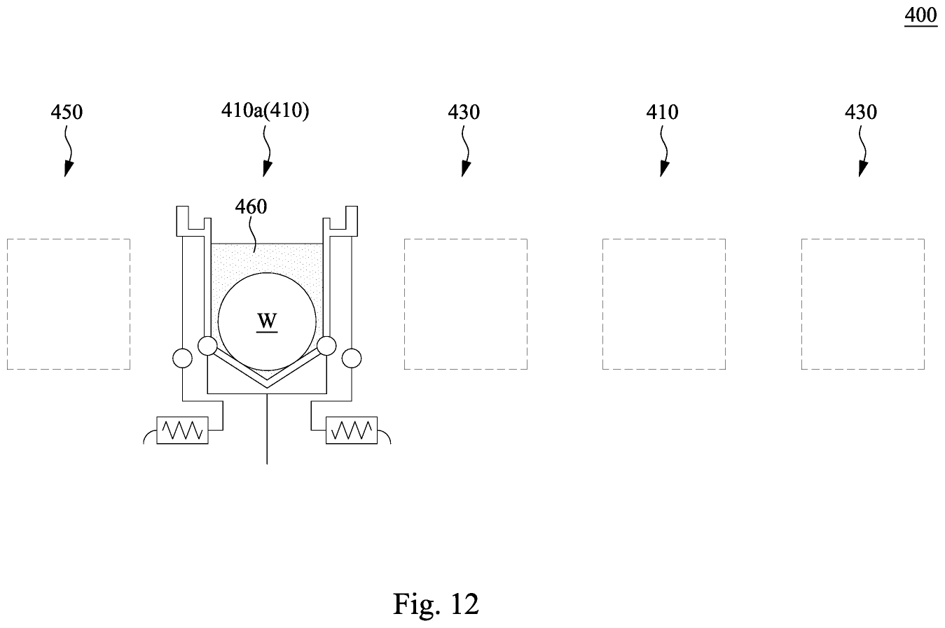

Still referring to FIG. 7, the block S105 then proceeds to step S1057A where the batch of wafers are cleaned in the first treatment chamber, in some embodiments of the disclosure. With reference to FIG. 12, in some embodiments of step S1057A, the batch of wafers W returns to the first treatment chamber 410a and is soaked in the cleaning chemical 460 again, to remove contaminants on the surface of the wafers W. In some embodiments, the cleaning chemical 460 is heated, and the temperature of the heated cleaning chemical 460 is in a range from about 25° C. to about 60° C. If the temperature of the cleaning chemical 460 is greater than about 60° C., the oxide film etching loss might be the process concern; if the temperature of the cleaning chemical 460 is lower than about 25° C., the cleaning efficiency not enough for impurity removal. In some embodiments, the batch of wafers W is soaked in the first treatment chamber 410a for about 120 seconds to about 600 seconds. If the time of the batch of wafers W soaked in the cleaning chemical 460 is greater than about 600 seconds, the wafer process time would be too long and is not economical for manufacturing industry; if the time of the batch of wafers W soaked in the cleaning chemical 460 is shorter than about 120 seconds, the liquid replacement (e.g. draining and filling) time would be not enough and thus water mark defect might be occurred. It is understood that details of the processing chambers 430 and the drying chamber 450 are not shown in FIG. 12.

Returning to FIG. 7, the block S105 then proceeds to step S1058A where the batch of wafers are transferred from the first treatment chamber to a drying chamber, in some embodiments of the disclosure.

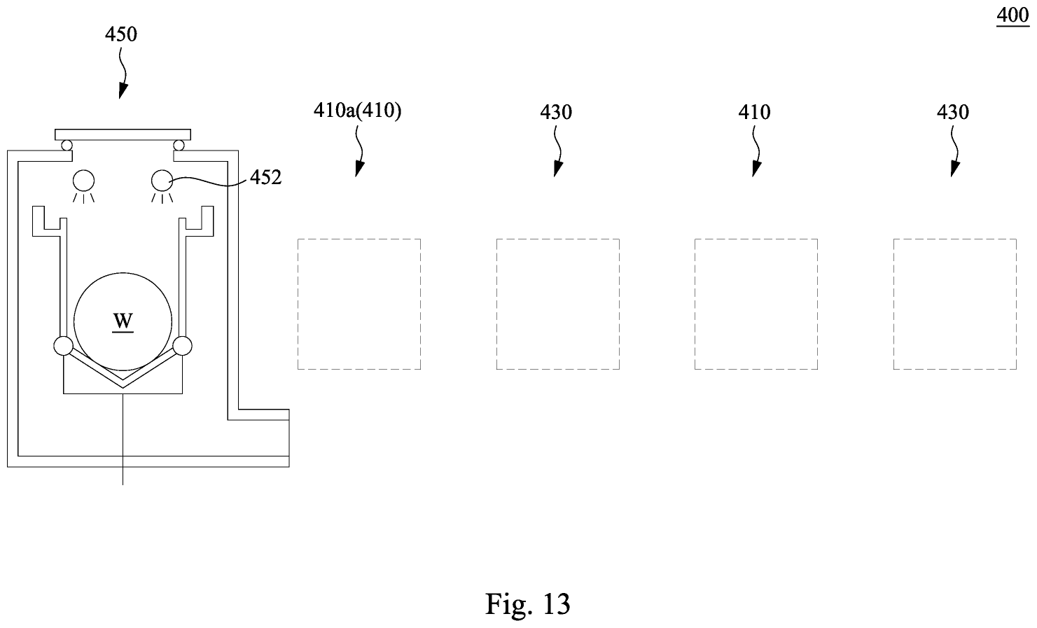

Still referring to FIG. 7, the block S105 then proceeds to step S1059 where the batch of wafers is dried in the drying chamber. With reference to FIG. 13, in some embodiments of step S1059, the batch of wafers W is dried in the drying chamber 450. It is understood that details of the treatment chambers 410 and the processing chambers 430 are not shown in FIG. 13.

In some embodiments, an isopropyl alcohol (IPA) drying process is used to dry the batch of the wafers W. The drying chamber 450 has at least one sprayer 452 disposed at the top of the drying chamber 450. The sprayer 452 is configured to dispense hot vapor of IPA in the drying chamber 450. In some embodiments, the direction of the hot vapor of IPA dispensed on the wafers W is parallel to the surface of the wafer W. For example, the batch of wafers W is vertically disposed in the drying chamber 450, and the hot vapor of IPA is dispensed on the surface of the wafers W through the spaces therebetween. In some embodiments, the temperature of the hot vapor of IPA is in a range from about 50° C. to about 80° C., and the IPA evaporates during a cooling process, leaving the wafers W moisture-free. In some embodiments, an inert gas such as N₂ or other inactive gases is blown through the surface of the wafers W to dry the wafers W.

Returning to FIG. 7, in some other embodiments, following step S1055, the block S105 then proceeds to step S1056B where the batch of wafers are transferred from the processing chamber to a second treatment chamber, in some embodiments of the disclosure.

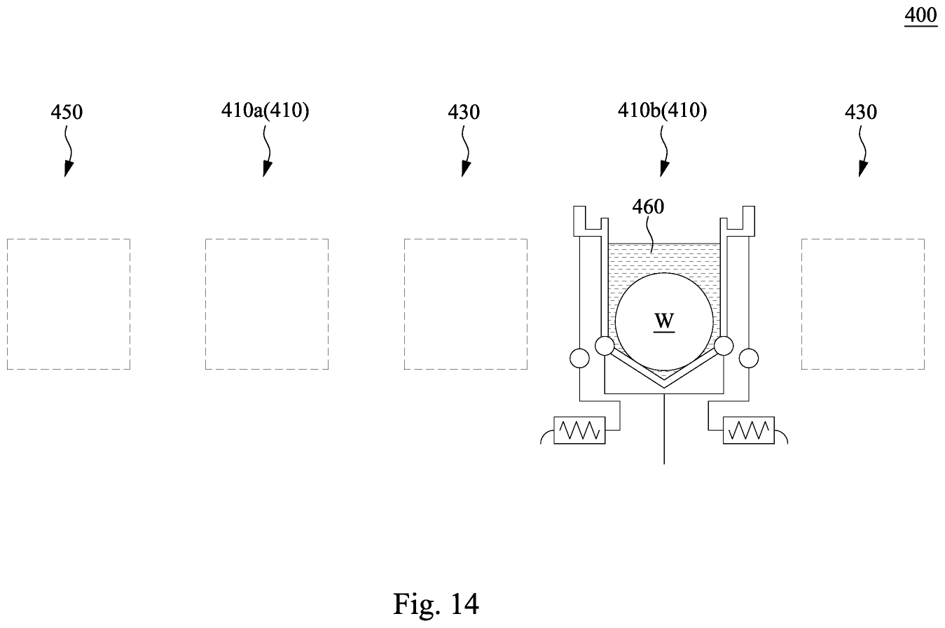

Still referring to FIG. 7, the block S105 then proceeds to step S1057B where the batch of wafers are cleaned in the second treatment chamber, in some embodiments of the disclosure. With reference to FIG. 14, in some embodiments of step S1057B, the batch of wafers W is transferred to the second treatment chamber 410b and is soaked in the cleaning chemical 460 again, to remove contaminants on the surface of the wafers W. The arrangement of the second treatment chamber 410b is substantially the same as the first treatment chamber 410a. It is understood that details of the process chambers 430 and the drying chamber 450 are not shown in FIG. 14. In some embodiments, the cleaning chemical 460 is heated, and the temperature of the heated cleaning chemical 460 is in a range from about 25° C. to about 60° C. If the temperature of the cleaning chemical 460 is greater than about 60° C., the oxide film etching loss might be the process concern; if the temperature of the cleaning chemical 460 is lower than about 25° C., the cleaning efficiency not enough for impurity removal. In some embodiments, the batch of wafers W is soaked in the first treatment chamber 410a for about 120 seconds to about 600 seconds. If the time of the batch of wafers W soaked in the cleaning chemical 460 is greater than about 600 seconds, the wafer process time would be too long and is not economical for manufacturing industry; if the time of the batch of wafers W soaked in the cleaning chemical 460 is shorter than about 120 seconds, the liquid replacement (e.g. draining and filling) time is not enough and thus water mark defect might be occurred. In some embodiments, the cleaning chemical 460 is a standard clean-1 (SC1).

Returning to FIG. 7, the block S105 then proceeds to step S1058B where the batch of wafers are transferred from the second treatment chamber to the drying chamber, in some embodiments of the disclosure. The step S1058B is then followed by drying step S1059.

Reference is made back to FIG. 6. In some embodiments, after proceeding the block S105, a portion of the dummy fin 174 is removed by the described wet etching processes, and a top surface 174t of the dummy fin 174 is lower than top surfaces of the semiconductor fins 112 and 114. In some embodiments, the top surface 174t of the dummy fin 174 may be at an intermediate level between the semiconductor fins 112 and 114 and the topmost surface of the spacing layer material 120′. In some embodiments, the top surface 174t of the dummy fin 174 has a substantially flat plane.

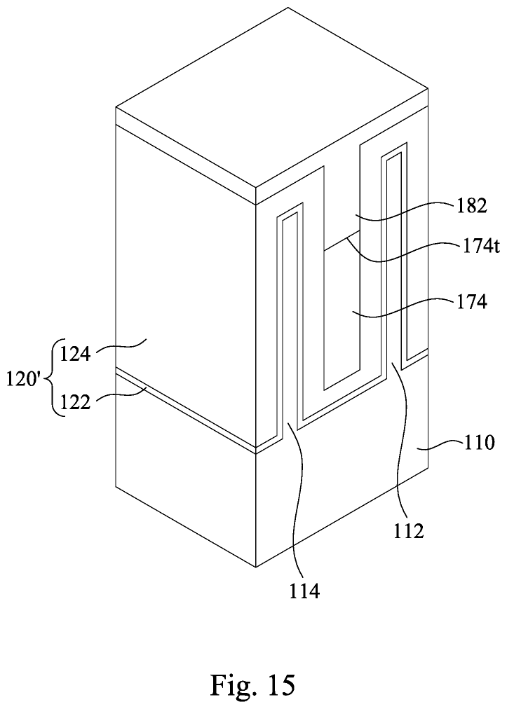

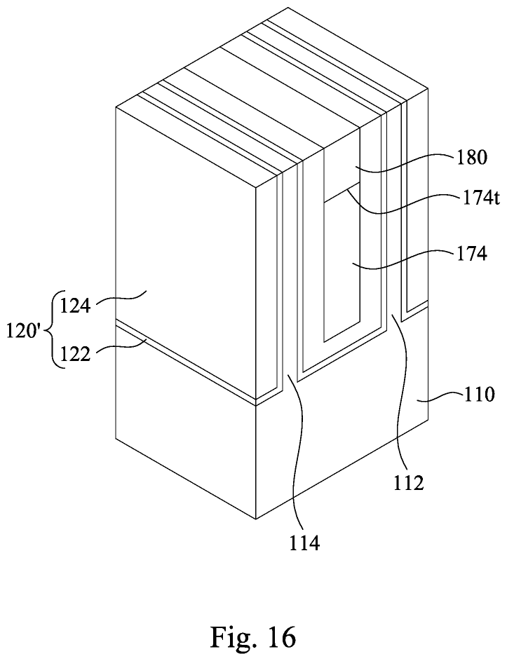

Returning to FIG. 1, the method M then proceeds to block S106 where a hard mask structure is formed over the dummy fin in the recess. With reference to FIGS. 15 and 16, in some embodiments of block S106, a hard mask layer 182 is conformally formed over the spacing layer material 120′ and the dummy fin 174. In some embodiments, an atomic layer deposition (ALD) process P1 is employed to form the hard mask layer 182. As a result, the thickness of the hard mask layer 182 can be controlled using cycle times of the ALD process. In some embodiments, the ALD process may include a plurality of cycles to form the hard mask layer 182. In some embodiments, the hard mask layer 182 may be made of HfO₂. By way of example but not limitation, the ALD process is performed using a hafnium precursor and an oxidant co-precursor to deposit the hard mask layer 182. By way of example but not limitation, the hafnium precursor may include tetrakis (ethylmethylamino) hafnium (TEMAH), tetrakis-diethylamido hafnium (i.e., Hf[N(C₂H₅)₂]₄, TDEAHf), Hf(OC(CH₃)₃)₄ (i.e., Hf-t-butoxide), HfCl₄, or any other suitable hafnium precursor. The oxidant co-precursor may include H₂O, O₃ and O₂ plasma, or any other suitable oxidant co-precursor.

Additionally, a planarization (e.g., CMP) process is performed to remove excess portion of the hard mask layer 182 and the spacing layer material 120′ above the semiconductor fins 112 and 114 to form a hard mask structure 180 over the top surface 174t of the dummy fin 174, as shown in FIG. 16.

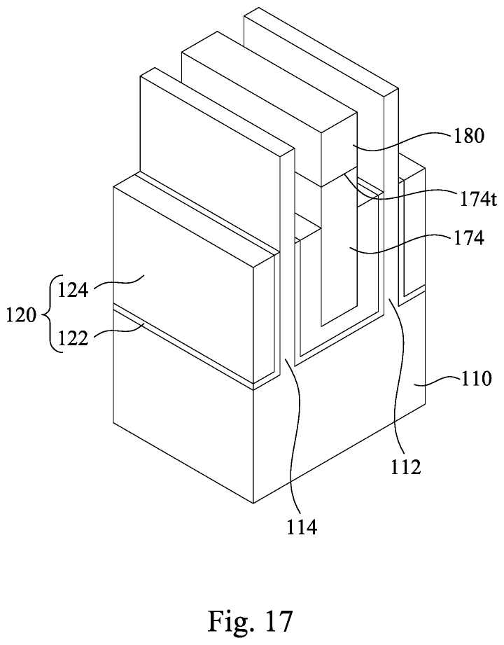

Returning to FIG. 1, the method M then proceeds to block S107 where the spacing layer material is etched back such that portions of the semiconductor fins and the dummy fin having the hard mask structure thereon protrude from the remaining portions of the spacing layer material. With reference to FIG. 17, in some embodiments of block S107, the spacing layer material 120′ (see FIG. 16) is then etched back such that portions of the semiconductor fins 112 and 114 and the dummy fin 174 having the hard mask structure 180 thereon protrude from the remaining portions of the spacing layer material 120′. The remaining portions of spacing layer material 120′ forms spacing layer 120. The spacing layer 120 can also be referred to as a shallow trench isolation (STI) structure between the semiconductor fins 112 and 114 and the dummy fin 174. The spacing layer 120 can be achieved by suitable methods such as, for example, an etch process that has suitable etch selectivity between materials of the spacing layer material 120′, the semiconductor fins 112 and 114, the dummy fin 174, and the hard mask structure 180. For example, the etch process can have a higher etch rate of the spacing layer material 120′ than the etch rate of the semiconductor fins 112 and 114, the dummy fin 174, and/or the hard mask structure 180. In some embodiments, etching rate difference be achieved by adjusting suitable parameters of the etch process such as, for example, etchant gas type, gas flow rate, etching temperature, plasma power, chamber pressure, other suitable parameters, and/or combinations thereof.

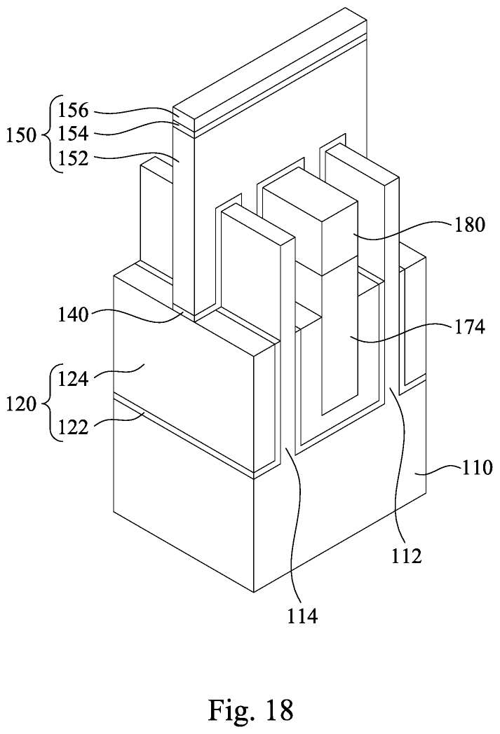

Returning to FIG. 1, the method M then proceeds to block S108 where a dummy gate structure is formed across the semiconductor fins and the dummy fin having the hard mask structure thereon. With reference to FIG. 18, in some embodiments of block S108, a sacrificial gate dielectric layer 140 is conformally formed above the structure of FIG. 17. In some embodiments, the sacrificial gate dielectric layer 140 may include silicon dioxide, silicon nitride, a high-κ dielectric material or other suitable material. In various examples, the sacrificial gate dielectric layer 140 may be deposited by an ALD process, a CVD process, a subatmospheric CVD (SACVD) process, a flowable CVD process, a PVD process, or other suitable process. By way of example, the sacrificial gate dielectric layer 140 may be used to prevent damage to the semiconductor fins 112 and 114 by subsequent processing (e.g., subsequent formation of the dummy gate structure).

Subsequently, a dummy gate structure 150 is formed above the sacrificial gate dielectric layer 140. The dummy gate structure 150 includes a dummy gate layer 152, a pad layer 154 formed over the dummy gate layer 152, and a mask layer 156 formed over the pad layer 154. Formation of the dummy gate structure 150 includes depositing in sequence a dummy gate layer, a pad layer and a mask layer over the substrate 110, patterning the pad layer and mask layer into patterned pad layer 154 and mask layer 156 using suitable photolithography and etching techniques, followed by patterning the dummy gate layer using the pad layer 154 and the mask layer 156 as masks to form the patterned dummy gate layer 152. As such, the dummy gate layer 152, the pad layer 154, and the mask layer 156 are referred to as the dummy gate structure 150. The sacrificial gate dielectric layer 140 is then patterned using the dummy gate structure 150 as an etching mask. In some embodiments, the dummy gate layer 152 may be made of polycrystalline-silicon (poly-Si), poly-crystalline silicon-germanium (poly-SiGe), or other suitable materials. The pad layer 154 may be made of silicon nitride or other suitable materials, and the mask layer 156 may be made of silicon dioxide or other suitable materials.

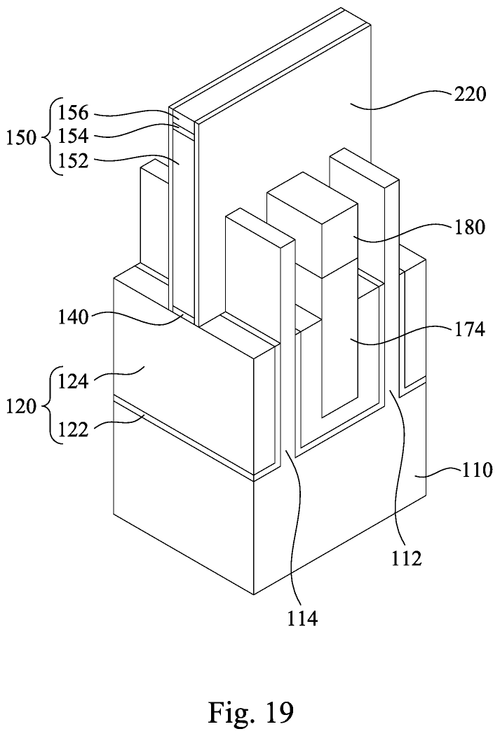

Returning to FIG. 1, the method M then proceeds to block S109 where gate spacers are respectively formed on sidewalls of the dummy gate structure. With reference to FIG. 19, in some embodiments of block S109, gate spacers 220 are respectively formed on sidewalls of the dummy gate structure 150. The gate spacers 220 may include a seal spacer and a main spacer (not shown). The gate spacers 220 include one or more dielectric materials, such as silicon oxide, silicon nitride, silicon oxynitride, SiCN, SiCₓO_{y}N_{z}, or combinations thereof. The seal spacers are formed on sidewalls of the dummy gate structure 150 and the main spacers are formed on the seal spacers. The gate spacers 220 can be formed using a deposition method, such as plasma enhanced chemical vapor deposition (PECVD), low-pressure chemical vapor deposition (LPCVD), sub-atmospheric chemical vapor deposition (SACVD), or the like. The formation of the gate spacers 220 may include blanket forming spacer layers, and then performing etching operations to remove the horizontal portions of the spacer layers. The remaining vertical portions of the gate spacer layers form the gate spacers 220.

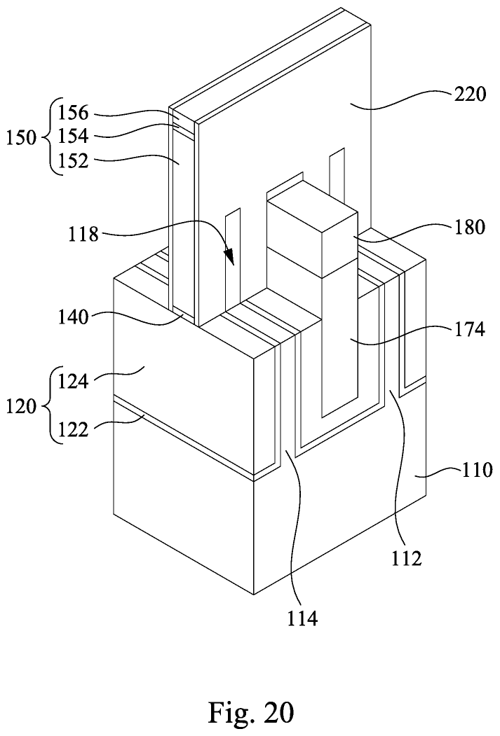

Returning to FIG. 1, the method M then proceeds to block S110 where a plurality of recesses are formed on opposite sides of the dummy gate structure by etching the semiconductor fins. With reference to FIG. 20, in some embodiments of block S110, recesses 118 are formed on opposite sides of the dummy gate structure 150 by etching the semiconductor fins 112 and 114. The dummy gate structure 150 and the gate spacers 220 act as etching masks in the formation of the recesses 118. The etching process includes a dry etching process, a wet etching process, or combinations thereof.

During this etching process, the hard mask structure 180 is recessed at the areas not covered by the dummy gate structure 150 or the gate spacers 220. In some embodiments, the etching process is performed with an anisotropic dry etch process. In some embodiments, the dry etch process etches the semiconductor fins 112 and 114 (e.g., Si, Ge, and/or SiGe) much faster than etching the hard mask structure 180 (e.g., metal oxides, SiON, and SiOCN). Due to this etch selectivity, the dry etch process patterns the semiconductor fins 112 and 114 vertically without complete etching the hard mask structure 180. In FIG. 19, portions of the hard mask structure 180 covered by the dummy gate structure 150 or the gate spacers 220 has a height greater than a height of the recessed portion of the hard mask structure 180.

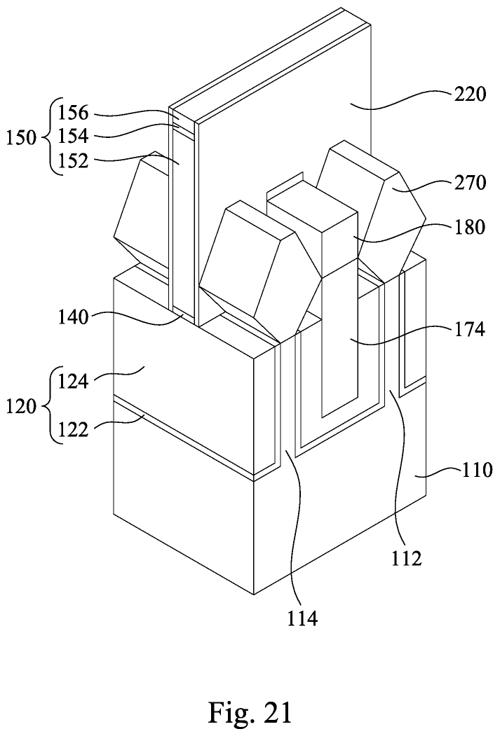

Returning to FIG. 1, the method M then proceeds to block S111 where semiconductor materials are then deposited in the recesses to form epitaxial structures. With reference to FIG. 21, in some embodiments of block S111, semiconductor materials are then deposited in the recesses 118 (see FIG. 20) to form epitaxial structures 270 which are referred to as source/drain regions. The epitaxial structures 270 are form above the N-type region and/or the P-type region. The epitaxial structures 270 may alternatively be referred to as raised source and drain regions.

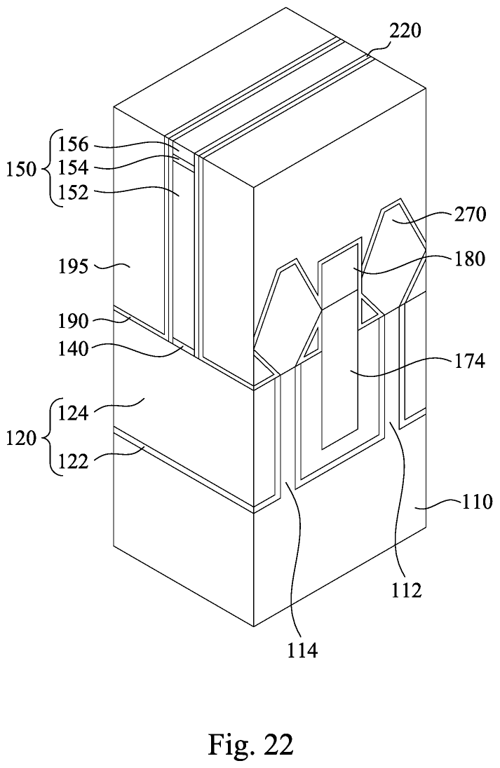

Returning to FIG. 1, the method M then proceeds to block S112 where a contact etch stop layer (CESL) is conformally formed over the substrate and an interlayer dielectric (ILD) is then formed on the CESL. With reference to FIG. 22 in some embodiments of block S112, a contact etch stop layer (CESL) 190 is conformally formed over the structure of FIG. 21 The CESL 190 extends along top surfaces of the hard mask structure 180. The CESL 190 can be a stressed layer or layers. In some embodiments, the CESL 190 has a tensile stress and is formed of Si₃N₄. In some other embodiments, the CESL 190 includes materials such as oxynitrides. In yet some other embodiments, the CESL 190 may have a composite structure including a plurality of layers, such as a silicon nitride layer overlying a silicon oxide layer. The CESL 190 can be formed using plasma enhanced CVD (PECVD), however, other suitable methods, such as low pressure CVD (LPCVD), atomic layer deposition (ALD), and the like, can also be used.

An interlayer dielectric (ILD) 195 is then formed on the CESL 190. The ILD 195 may be formed by chemical vapor deposition (CVD), high-density plasma CVD, spin-on, sputtering, or other suitable methods. In some embodiments, the ILD 195 includes silicon oxide. In some other embodiments, the ILD 195 may include silicon oxy-nitride, silicon nitride, compounds including Si, O, C and/or H (e.g., silicon oxide, SiCOH and SiOC), a low-k material, or organic materials (e.g., polymers). After the ILD 195 is formed, a planarization operation, such as CMP, is performed, so that the pad layer 154 and the mask layer 156 are removed and the dummy gate layer 152 is exposed.

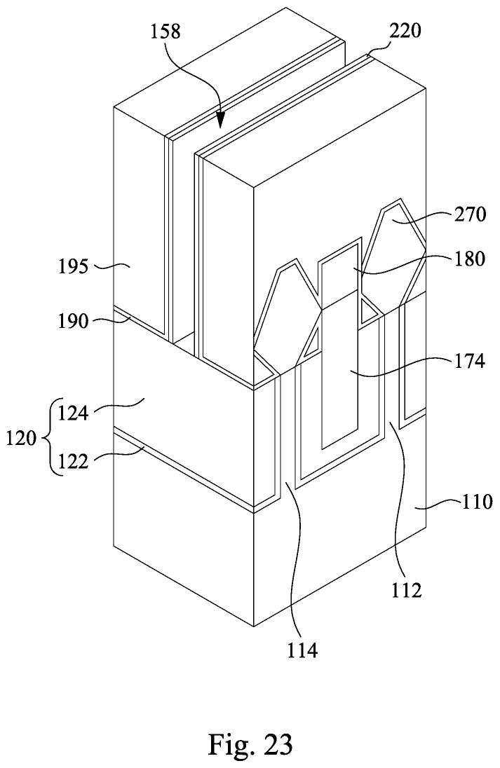

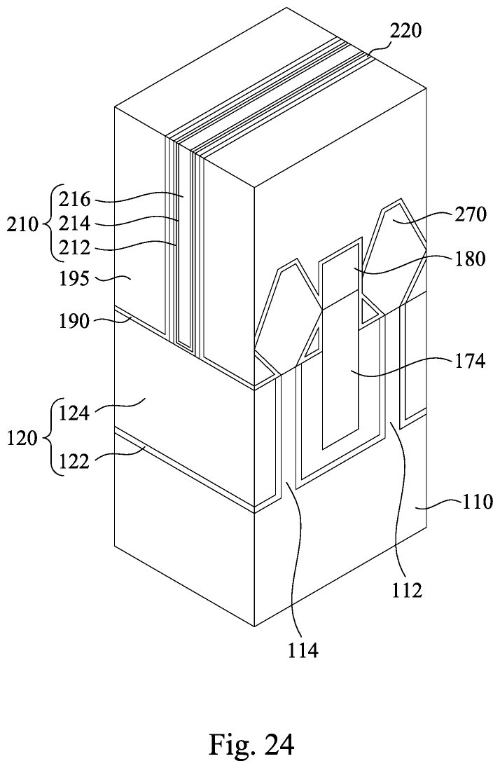

Returning to FIG. 1, the method M then proceeds to block S113 where a replacement gate (RPG) process scheme is employed. With reference to FIGS. 23 and 24, in some embodiments of block S113, subsequently and optionally, a replacement gate (RPG) process scheme is employed. In the RPG process scheme, a dummy polysilicon gate (the dummy gate structure 150 in FIG. 22 in this case) is formed in advance and is replaced later by a metal gate. In some embodiments, the dummy gate structure 150 is removed to form a gate trench 158 with the gate spacers 220 as its sidewalls. In some other embodiments, the sacrificial gate dielectric layer 140 (see FIG. 22) is removed as well. The dummy gate structure 150 and the sacrificial gate dielectric layer 140 may be removed by dry etching, wet etching, or a combination of dry and wet etching.

A gate dielectric layer 212 is formed in the gate trench 158, and at least one metal layer is formed in the gate trench 158 and on the gate dielectric layer 212. Subsequently, a chemical mechanical planarization (CMP) process is performed to planarize the metal layer and the gate dielectric layer 212 to form a metal gate structure 210 in the gate trench 158.

In some embodiments, the gate dielectric layer 212 includes a high-k material (k is greater than about 7) such as hafnium oxide (HfO₂), zirconium oxide (ZrO₂), lanthanum oxide (La₂O₃), hafnium aluminum oxide (HfAlO₂), hafnium silicon oxide (HfSiO₂), aluminum oxide (Al₂O₃), or other suitable materials. In some embodiments, the gate dielectric layer 212 may be formed by performing an ALD process or other suitable process. The metal gate electrode may include at least one work function metal layer 214, a fill layer 216, and/or other suitable layers that are desirable in a metal gate stack. The work function metal layer 214 may include an n-type and/or a p-type work function metal. Exemplary n-type work function metals include Ti, Ag, TaAl, TaAlC, TiAlN, TaC, TaCN, TaSiN, Mn, Zr, other suitable n-type work function materials, or combinations thereof. Exemplary p-type work function metals include TiN, TaN, Ru, Mo, Al, WN, ZrSi₂, MoSi₂, TaSi₂, NiSi₂, WN, other suitable p-type work function materials, or combinations thereof. The work function metal layer 214 may have multiple layers and may be deposited by CVD, PVD, electroplating and/or other suitable processes. In some embodiments, the capping layer may include refractory metals and their nitrides (e.g., TiN, TaN, W₂N, TiSiN, and TaSiN). The capping layer may be deposited by PVD, CVD, metal-organic chemical vapor deposition (MOCVD) ALD, or the like. In some embodiments, the fill layer 216 may include tungsten (W). The fill layer 216 may be deposited by ALD, PVD, CVD, or another suitable process.

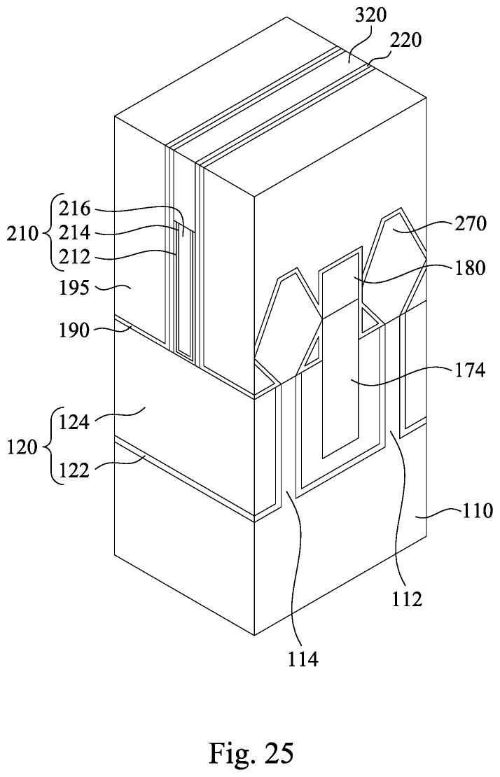

Returning to FIG. 1, the method M then proceeds to block S114 where a capping layer is formed to define self-aligned contact region. With reference to FIG. 25, in some embodiments of block S114, subsequently and optionally, the metal gate structure 210 is etched back to a predetermined level and form a gate trench thereon. As such, a portion of the hard mask structure 180 protrudes from the metal gate structure 210 while the hard mask structure 180 is embedded in the metal gate structure 210. Then, a capping layer 320 is formed over the etched metal gate structure 210 using, for example, a deposition process to deposit a dielectric material over the substrate 110, followed by a CMP process to remove excess dielectric material outside the gate trenches. In some embodiments, the capping layer 320 includes silicon nitride, silicon oxide, silicon oxynitride, SiCN, SiCON, SiOC, or other suitable dielectric material. By way of example, if the capping layer 320 is SiN, the gate spacers 220 and/or the ILD 195 are dielectric materials different from SiN. The capping layer 320 can be used to define self-aligned contact region and thus referred to as SAC structures or a SAC layer. The capping layer 320 is in contact with the gate dielectric layer 212, the work function metal layer 214, and the fill layer 216, and a portion of the hard mask structure 180 is embedded in the capping layer 320.

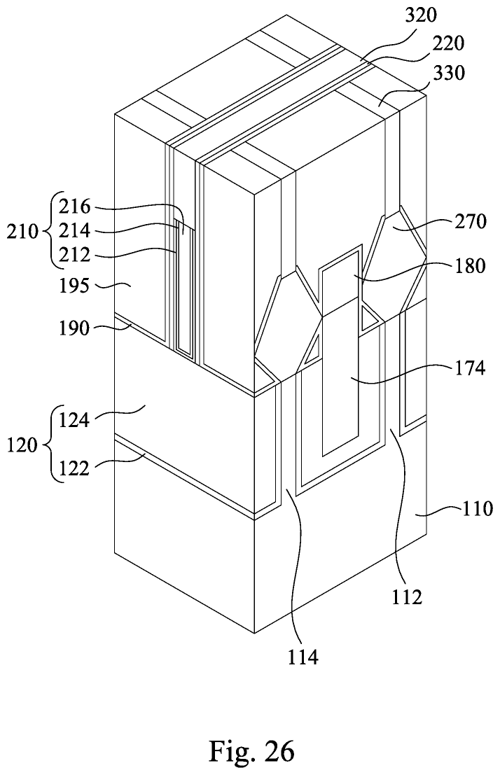

Returning to FIG. 1, the method M then proceeds to block S115 where contacts are formed to land on the epitaxial structures. With reference to FIG. 26, in some embodiments of block S115, the ILD 195 is patterned to form trenches on opposite sides of the metal gate structure 210 and the capping layer 320, and then the CESL 190 is patterned to expose the epitaxial structures 270. In some embodiments, multiple etching processes are performed to pattern the ILD 195 and the CESL 190. The etching processes include dry etching process, wet etching process, or combinations thereof. Then, contacts 330 are formed in the trenches. As such, the contacts 330 are respectively in contact with the epitaxial structures 270. In some embodiments, the contacts 330 may be made of metal, such as W, Co, Ru, Al, Cu, or other suitable materials. After the deposition of the contacts 330, a planarization process, such as a chemical mechanical planarization (CMP) process, may be then performed. As such, a top surface of the contacts 330 and a top surface of the ILD 195 are substantially coplanar. In some embodiments, metal alloy layers (such as silicide) may be formed between the contacts 330 and the epitaxial structures 270. Further, barrier layers may be formed in the trenches before the formation of the contacts 330. The barrier layers may be made of TiN, TaN, or combinations thereof.

According to some embodiments of the disclosure, a method includes soaking a batch of wafers in a first cleaning liquid, wherein the first cleaning liquid has a first temperature; replacing the first cleaning liquid with a second cleaning liquid, wherein the second cleaning liquid has a second temperature; soaking the batch of wafers in the second cleaning liquid; and soaking the batch of wafers in an etchant, wherein the etchant has a third temperature, and the second temperature is between the first temperature and the third temperature.

According to some other embodiments of the disclosure, a method includes soaking a batch of wafers in a first mixture comprising standard clean-1 (SC1) in a first treatment chamber; draining the first mixture from the first treatment chamber; soaking the batch of wafers in a heated deionized water (DI water) in the first treatment chamber, wherein a temperature of the heated DI water is higher than a temperature of the first mixture; transferring the batch of wafers from the first treatment chamber to a processing chamber; and wet-etching the batch of wafers in the processing chamber.

According to some other embodiments of the disclosure, a method includes forming a structure having a dummy fin between semiconductor fins; pre-cleaning the structure, wherein the structure is heated at least once during the pre-cleaning the structure; selectively etching the structure, such that a portion of the dummy fin is removed thereby forming a recess thereon; and post-cleaning the structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
soaking a batch of wafers in a first cleaning liquid, wherein the first cleaning liquid has a first temperature;
replacing the first cleaning liquid with a second cleaning liquid, wherein the second cleaning liquid has a second temperature;
soaking the batch of wafers in the second cleaning liquid; and
soaking the batch of wafers in an etchant, wherein the etchant has a third temperature, and the second temperature is between the first temperature and the third temperature.

2. The method of claim 1, wherein soaking the batch of wafers in an etchant is performed after soaking the batch of wafers in the second cleaning liquid.

3. The method of claim 1, wherein the first temperature is in a range from about 25° C. to about 60° C.

4. The method of claim 1, wherein the first cleaning liquid is a standard clean-1 (SC1).

5. The method of claim 1, wherein the batch of wafers is soaked in the first cleaning liquid from about 120 seconds to about 600 seconds.

6. The method of claim 1, wherein the second cleaning liquid is a deionized water (DI water).

7. The method of claim 1, wherein the second temperature is in a range from about 60° C. to about 90° C.

8. The method of claim 1, wherein the batch of wafers is soaked in the second cleaning liquid from about 60 seconds to about 120 seconds.

9. The method of claim 1, wherein the etchant is a mixture of phosphoric acid (H₃PO₄) and water (H₂O).

10. The method of claim 1, wherein the batch of wafers is soaked in the etchant from about 50 seconds to about 600 seconds.

11. The method of claim 1, wherein the third temperature is in a range from about 140° C. to about 180° C.

12. A method, comprising:
soaking a batch of wafers in a first mixture comprising standard clean-1 (SC1) in a first treatment chamber;
draining the first mixture from the first treatment chamber;
soaking the batch of wafers in a heated deionized water (DI water) in the first treatment chamber, wherein a temperature of the heated DI water is higher than a temperature of the first mixture;
transferring the batch of wafers from the first treatment chamber to a processing chamber; and
wet-etching the batch of wafers in the processing chamber.

13. The method of claim 12, further comprising:
after wet-etching the batch of wafers, transferring the batch of wafers from the processing chamber to the first treatment chamber; and
soaking the batch of wafers in a second mixture comprising SC1 in the first treatment chamber.

14. The method of claim 12, further comprising:
after wet-etching the batch of wafers, transferring the batch of wafers from the processing chamber to a second treatment chamber; and
soaking the batch of wafers in a second mixture comprising SC1 in the second treatment chamber.

15. The method of claim 12, further comprising:
drying the batch of wafers in a drying chamber.

16. The method of claim 15, wherein drying the batch of wafers comprises using an isopropyl alcohol.

17. The method of claim 16, wherein the isopropyl alcohol is dispensed in a direction parallel to a surface of the batch of wafers.

18. A method, comprising:
forming a structure having a dummy fin between semiconductor fins;
pre-cleaning the structure, wherein the structure is heated at least once during the pre-cleaning the structure;
selectively etching the structure, such that a portion of the dummy fin is removed thereby forming a recess thereon; and
post-cleaning the structure.

19. The method of claim 18, wherein the dummy fin has a flat top surface after selectively etching the structure.

20. The method of claim 18, wherein forming the structure comprises forming a spacing layer material on the semiconductor fins, and the dummy fin is defined by a trench between portions of the spacing layer material on sidewalls of the semiconductor fins.
